(19) United States
(12) Patent Application Publication
(10) Pub. No.: US 2019/0097735 A1
(43) Pub. Date: Mar. 28, 2019

(54) OPTICAL MODULE

(71) Applicant: FUJITSU COMPONENT LIMITED, Tokyo (JP)

(72) Inventors: Shinichiro Akieda, Tokyo (JP); Osamu Daikuhara, Tokyo (JP); Hongfei Zhang, Tokyo (JP)

(21) Appl. No.: 16/136,675

(22) Filed: Sep. 20, 2018

(30) Foreign Application Priority Data
Sep. 28, 2017 (JP) 2017-188251

(51) Int. Cl. H04B 10/80; G02B 6/42; G02B 6/38; H01L 31/0232

(52) U.S. Cl. CPC H04B 10/801; G02B 6/4266; G02B 6/3814; H01L 31/0232; G02B 6/4257; G02B 6/428; G02B 6/3873; G02B 6/3853

(57) ABSTRACT

An optical module includes a housing having an upper cover and a lower cover; a substrate having a circuit device mounted on its first surface; a heat dissipation member configured to be in contact with the circuit device mounted on the substrate; and at least one inner case having stiffness, wherein the upper cover is disposed facing the first surface of the substrate, and the lower cover is disposed facing a second surface of the substrate, and the inner case is disposed so as to press the substrate from the second surface of the substrate toward the upper cover.

### CROSS-REFERENCE TO RELATED APPLICATIONS

This application is based upon and claims priority to Japanese Patent Application No. 2017-188251, filed on Sep. 28, 2017, the entire contents of which are incorporated herein by reference.

### BACKGROUND OF THE INVENTION

### 1. Field of the Invention

The disclosures herein generally relate to an optical module.

### 2. Description of the Related Art

Optical communications are becoming widely used in the field of supercomputers and high-end servers supporting high-speed signal transmission via high-speed interfaces. In particular, for next-generation interfaces currently developed, such as InfiniBand Trade Association (IBTA) EDR (registered trademark) and 100G Ethernet (registered trademark), optical communications are used because of a long signal transmission distance. In optical communications, optical modules are used to convert an electrical signal into an optical signal. The optical module converts an input optical signal into an electrical signal. Also, the optical module converts an input electrical signal into an optical signal.

The optical module includes a light emitter that converts an electrical signal into an optical signal, a light receiver that converts an optical signal into an electrical signal, a drive IC (integrated circuit) that drives the light emitter, and a TIA (transimpedance amplifier) that converts an electrical current into voltage. The light emitter, the light receiver and semiconductor devices such as the drive IC and the TIA are mounted on a FPC (flexible printed circuit).

The devices mounted on the FPC generate heat when the optical module is in operation, resulting in an elevated temperature. In order to prevent a failure due to such heat, Patent Document 1 discloses a heat dissipation sheet disposed above a surface of a FPC on which devices are mounted, and is interposed between an upper cover and a lower cover. Accordingly, the dissipation sheet is brought into contact with the upper cover, and compressive stress is applied. This improves the efficiency of heat dissipation from the photoelectric conversion devices and the semiconductor devices.

When compressibility of the dissipation sheet is within a range of approximately 30% to 50%, the efficiency of heat dissipation improves. Thus, the dissipation sheet is preferably placed in the housing while being pressed such that the compressibility falls within the predetermined range. However, in Patent Document 1, because there are a number of parts between which the dissipation sheet is positioned, assembly dimensional tolerance becomes large, and a pressuring force applied to the dissipation sheet may become too weak or too strong. In this case, the compressibility falls outside the predetermined range and the photoelectric conversion devices and the semiconductor devices may fail to have a sufficient heat dissipation effect, and characteristics of the photoelectric conversion devices and the semiconductor devices may decrease.

### RELATED-ART DOCUMENTS

### Patent Documents

[Patent Document 1] Japanese Laid-open Patent Publication No. 2015-22129

### SUMMARY OF THE INVENTION

According to an embodiment, an optical module includes a housing having an upper cover and a lower cover; a substrate having a circuit device mounted on its first surface; a heat dissipation member configured to be in contact with the circuit device mounted on the substrate; and at least one inner case having stiffness, wherein the upper cover is disposed facing the first surface of the substrate, and the lower cover is disposed facing a second surface of the substrate, and the inner case is disposed so as to press the substrate from the second surface of the substrate toward the upper cover.

### BRIEF DESCRIPTION OF THE DRAWINGS

FIG. 1 is an exploded perspective view of an optical module according to a first embodiment;

FIG. 2 is a cross-sectional view of the optical module according to the first embodiment;

FIG. 3 is an exploded perspective view of an optical module according to a second embodiment;

FIG. 4 is a cross-sectional view of the optical module according to the second embodiment;

FIG. 5 is an exploded perspective view of an optical module according to a third embodiment;

FIG. 6 is a cross-sectional view of the optical module according to the third embodiment;

FIG. 7 is an exploded perspective view of an optical module according to a fourth embodiment; and

FIG. 8 is a cross-sectional view of the optical module according to the fourth embodiment.

### DESCRIPTION OF THE PREFERRED EMBODIMENTS

According to at least one embodiment, it is possible to provide an optical module having high efficiency of heat dissipation from a circuit device, such as a photoelectric conversion device and a semiconductor device, disposed in a housing.

In the following, embodiments of the present invention will be described with reference to the accompanying drawings. For convenience of explanation, the same elements are denoted by the same reference numerals in the drawings, and a duplicate description thereof will be omitted.

### First Embodiment

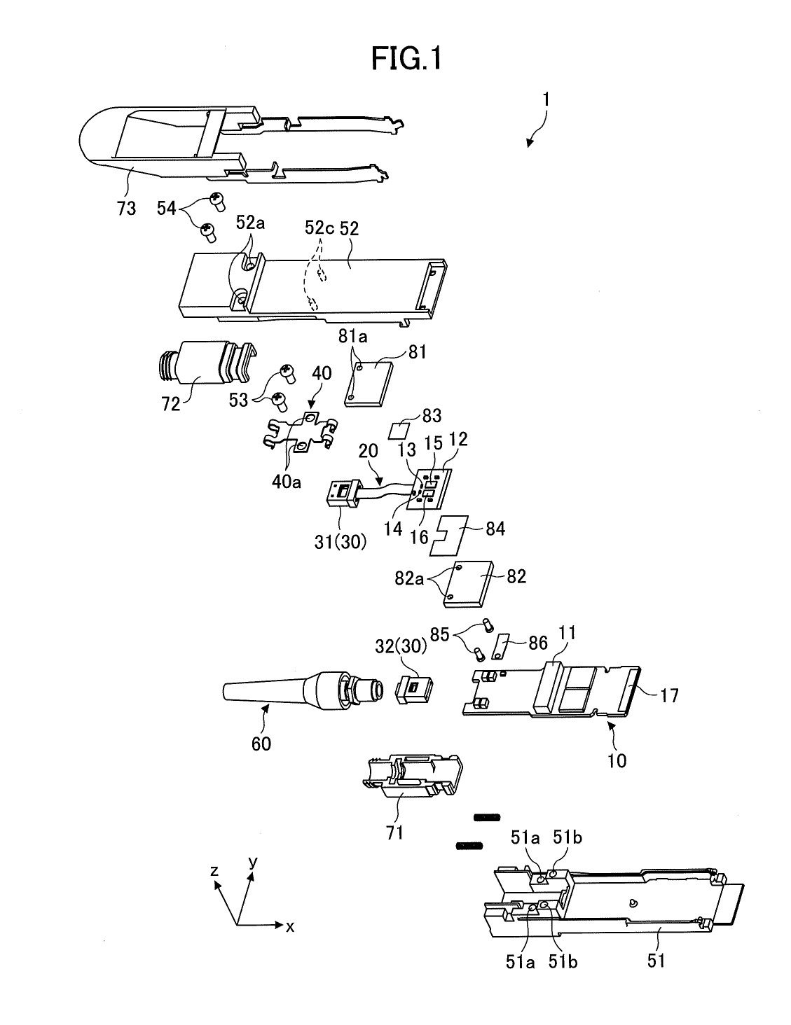

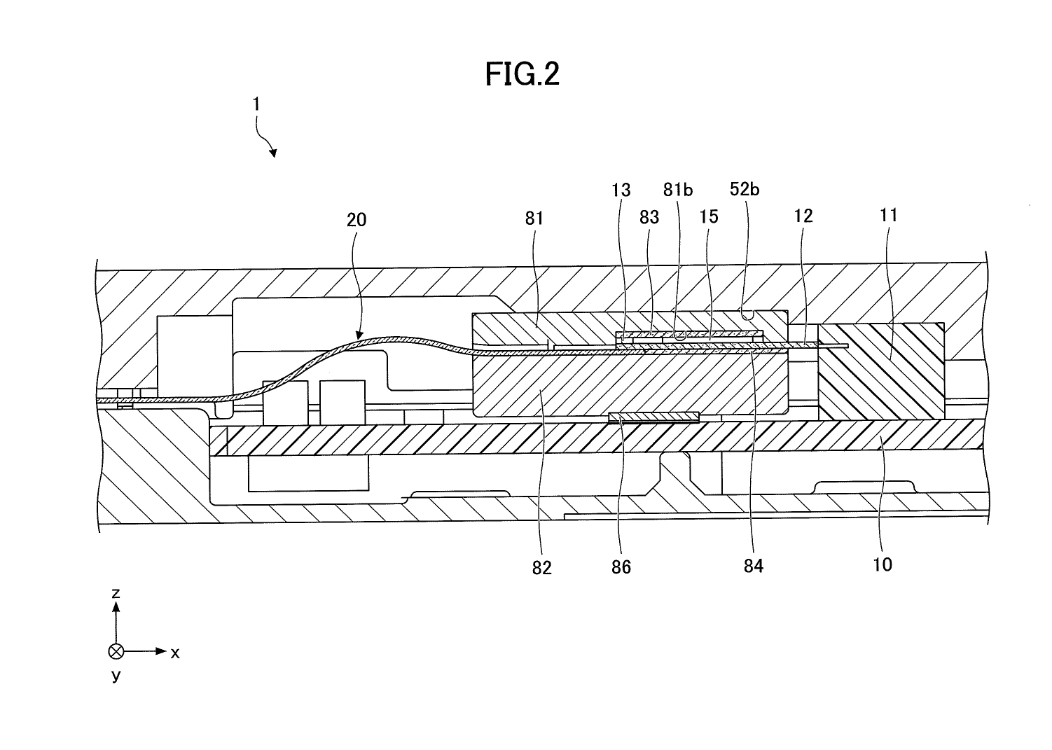

Referring to FIG. 1 and FIG. 2, a first embodiment will be described. FIG. 1 is an exploded perspective view of an optical module 1 according to the first embodiment. FIG. 2 is a cross-sectional view of the optical module 1. FIG. 2 is the cross-sectional view along a light transmission direction of the optical module 1 and denotes the vicinity of a FPC 12 in an enlarged view.

In the following, three axes (an x-axis, a y-axis, and a z-axis) perpendicular to each other are used as references to describe shapes of elements and positional relationships between the elements of the optical module 1. As illustrated in FIG. 1, the x-axis is the light transmission direction, the y-axis is a width direction of the optical module 1, and the z-axis is a stacked direction of main parts of the optical module 1. For example, the z-axis is a top-bottom direction, a surface in the positive z-direction (+Z side) is an upper surface, and a surface in the negative z-direction (−Z side) is a lower surface. Further, the x-axis and the y-axis are horizontal directions perpendicular to the z-axis. +x side is a side at which one end of the optical waveguide 20 is connected to the FPC 12. −x side is a side at which the other end of the optical waveguide 20 is connected to a lens ferrule 31. +y side is a side at which a light emitter 13 is disposed on the FPC 12, among elements mounted on the FPC 12. −y side is a side at which a light receiver 14 is disposed on the FPC 12.

As illustrated in FIG. 1, the optical module 1 includes a printed circuit board 10, an optical waveguide 20, a ferrule 30, and a clip 40 in a housing having a lower cover 51 and an upper cover 52. Also, an optical cable 60 is connected to the optical module 1. The upper cover 52 and the lower cover 51 are zinc die castings, for example.

A FPC connector 11 to which to connect the FPC 12 (a substrate) is provided on the printed circuit board 10. The light emitter 13 such as a vertical-cavity surface-emitting laser (VCSEL) that converts an electrical signal into an optical signal, the light receiver 14 such as a photodiode that converts an optical signal into an electrical signal, a drive IC 15 that drives the light emitter 13, and a TIA 16 that converts an electrical current from the light receiver 14 into voltage are mounted on the upper surface of the FPC 12. Also, a connection terminal 17 for external connection is provided on +x side. The printed circuit board 10 is placed on the lower cover 51.

In the present embodiment, the light emitter 13 and the light receiver 14 are collectively referred to as a “photoelectric conversion device”. Further, the drive IC 15 and the TIA 16 are collectively referred to as a “semiconductor device”. The photoelectric conversion device and the semiconductor device are collectively referred to as a “circuit device”.

The optical waveguide 20 is a flexible sheet-shaped optical waveguide and extends in x-direction. A +x side end of the optical waveguide 20 is connected to the FPC 12. A −x side end of the optical waveguide 20 is connected to the lens ferrule 31. A connection part of the optical waveguide 20 and the lens ferrule 31 is protected by a ferrule boot (not illustrated).

The ferrule 30 includes the lens ferrule 31 and a mechanically transferable (MT) ferrule 32. The lens ferrule 31 and the MT ferrule 32 are connected to each other along x-direction and are held by the clip 40 so as to be fixed. The MT ferrule 32 is a ferrule that can hold a multi-core optical fiber. The lens ferrule 31 is designed to have higher density than the MT ferrule 32. For example, in a Quad Small Form-factor Pluggable (QSFP) optical connector, by connecting and aligning the MT ferrule 32 with the lens ferrule 31, the optical cable 60 connected to the MT ferrule 32 and the optical waveguide connected to the lens ferrule 31 are coupled to each other.

The ferrule 30 is disposed above the lower cover 51. The clip 40 has two screw holes 40a. Once two threads 51a provided on the lower cover 51 are positioned to match the screw holes 40a, screws 53 are inserted. By screwing the clip 40 to the lower cover 51, the ferrule 30 is fixed to the lower cover 51 via the clip 40.

The FPC 12 is interposed between an upper inner case 81 and a lower inner case 82 and is held from above and below. The upper inner case 81 covers the upper surface of the FPC 12, and the lower inner case 82 covers the lower surface of the FPC 12. The upper inner case 81 and the lower inner case 82 are harder than the FPC 12, and are formed of a material having high heat dissipation efficiency. Also, the upper inner case 81 and the lower inner case 82 are formed of a material having stiffness. As used herein, “stiffness” means the extent to which a material resists a deformation in response to an applied force such as in bending or torsion. Having stiffness means less deformation and high stiffness under an applied force. Stiffness includes axial stiffness, bending stiffness, shear stiffness, and torsional stiffness.

Examples of the material of the upper inner case 81 and the lower inner case 82 include metal, ceramics, and plastic containing metal filler. For example, the upper inner case 81 and the lower inner case 82 may be manufactured by processes such as die-cast molding, cutting, press working, or bending.

A heat dissipation sheet 83 is placed above the upper surface of the FPC 12 on which the circuit devices are mounted. The heat dissipation sheet 83 conducts heat generated by the circuit devices toward the upper cover 52, such that heat is released. The heat dissipation sheet 83 is designed to have a size that allows the heat dissipation sheet 83 to make contact with at least upper surfaces of the circuit devices and cover the upper surfaces. The heat dissipation sheet 83 is inserted between the upper inner case 81 and the upper surface of the FPC 12. The heat dissipation sheet 83 is formed mainly of a silicon material and has flexibility.

An electric wave absorption sheet 84 for absorbing electric wave, an example of a wave absorption member, is placed between the lower surface of the FPC 12 and the lower inner case 82. The wave absorption sheet 84 has a cutout so as not to overlap the optical waveguide 20. Accordingly, when the wave absorption sheet 84 is inserted between the FPC 12 and the lower inner case 82, the wave absorption sheet 84 does not overlap the optical waveguide 20 in z-direction, as illustrated in FIG. 2.

As illustrated in FIG. 2, the lower surface of the upper inner case 81 is provided with a recess 81b such that the heat dissipation sheet 83 and the circuit devices mounted on the FPC 12 can be fitted in the recess 81b. As illustrated in FIG. 1, two through-holes 81a, 81a are provided at an end portion located on −x side of the upper inner case 81 and two through-holes 82a, 82a are provided at an end portion located on −x side of the lower inner case 82.

The upper inner case 81, the heat dissipation sheet 83, the FPC 12, the wave absorption sheet 84, and the lower inner case 82 are stacked in this order, and fixed to the upper cover 52. As illustrated in FIG. 2, the heat dissipation sheet 83 and the FPC 12 are fitted in the recess 81b of the upper inner case 81. Also, the wave absorption sheet 84 is provided on the lower surface of the FPC 12, and the lower inner case 82 is attached to the wave absorption sheet 84. The two through-holes 81a, 81a are positioned to match the two through-holes 82a, 82a. In this state, screws 85 are inserted into the through-holes 81a, 81a and through-holes 82a, 82a, and are fastened to two threads 52c provided on the lower surface of the upper cover 52.

Further, a leaf spring 86 is placed between the lower inner case 82 and the printed circuit board 10 located therebelow. The leaf spring is disposed approximately at the center of the lower inner case 82, and is preferably disposed right below the heat dissipation sheet 83. The leaf spring 86 is sandwiched between the lower inner case 82 and the printed circuit board 10 so as to apply a pressing force toward the upper cover 52.

Also, as illustrated in FIG. 2, a recess 52b is provided on the lower surface of the upper cover 52 at a position where the upper inner case 81 is attached, such that an upper portion of the upper inner case 81 can be fitted in the recess 52b. Therefore, the attached upper inner case 81 is prevented from being displaced in the horizontal directions.

The vicinity of the end of the optical cable 60 to which to connect the MT ferrule 32 is covered by cable boots 71 and 72 from above and below, and further, a latch is attached thereto.

The ferrule 30 is fixed to the lower cover 51 via the clip 40, and the printed circuit board 10 is mounted on the lower cover 51. Then, the upper cover 52 having the FPC 12 fixed to its lower surface is placed over the lower cover 51. In this state, two screw holes 52a of the upper cover 52 are positioned to match two threads 51b, and the upper cover 52 is screwed to the lower cover 51 with screws 54.

The optical module 1 according to the first embodiment includes the housing having the upper cover 52 and the lower cover 51, the FPC 12 on which the circuit devices are mounted, and the heat dissipation sheet 83 in contact with the light emitter 13, the light receiver 14, the drive IC 15, and the TIA 16 mounted on the FPC 12. The optical module 1 also includes the upper inner case 81 and the lower inner case 82 respectively disposed at the upper surface and the lower surface of the FPC 12. The upper inner case 81 and the lower inner case 82 are placed so as to apply a pressing force to the FPC 12 toward the upper cover 52.

In the optical module disclosed in Patent Document 1, the heat dissipation sheet is held by 6 parts corresponding to the upper cover 52, an electronic component such as the drive IC 15, the FPC 12, the wave absorption sheet 84, the printed circuit board 10, and the lower cover 51, and receives a pressing force from these parts. The parts holding the heat dissipation sheet 83 each have tolerances. When the number of parts is large, tolerance stacking increases in accordance with the number of parts. As a result, the final assembly dimensional tolerance becomes large. If the assembly dimensional tolerance is large, a range in which the heat dissipation sheet receives the pressing force expands. This may cause the pressing force to become too weak or too strong. In this case, compressibility of the heat dissipation sheet falls outside of a range of approximately 30% to 50%, failing to sufficiently release heat from the photoelectric conversion device and the semiconductor device mounted on the FPC. As a result, characteristics of the circuit devices decrease. Alternatively, when excessive force is applied to the circuit devices, the devices may be damaged.

Conversely, in the optical module 1, the heat dissipation sheet 83 is held by 5 parts of the upper inner case 81, the electronic component such as the drive IC 15, the FPC 12, the wave absorption sheet 84, and the lower inner case 82. Accordingly, as compared to the conventional configuration, the optical module 1 according to the first embodiment can reduce the number of parts involved in applying a pressing force to the heat dissipation sheet 83. As the number of parts decreases, assembly dimensional tolerance can be reduced. Thus, compressibility of the dissipation sheet 83 can be easily maintained in the appropriate range, and efficiency of heat dissipation from the photoelectric conversion device and the semiconductor device mounted on the FPC 12 inside the housing can be improved.

Further, in the first embodiment, the upper inner case 81 covers the upper surface of the FPC 12, and the lower inner case 82 covers the lower surface of the FPC 12. Although the FPC 12 is very thin and flexibly deforms, the upper inner case 81 and the lower inner case 82 have stiffness and are formed of a material harder than that of the FPC 12. Accordingly, by interposing the FPC 12 between the upper inner case 81 and the lower inner case 82, the FPC 12 can be surrounded by a rigid body. Thus, the flexibility of the FPC 12 can be suppressed such that the FPC 12 is not distorted. Accordingly, in an assembly process, the FPC 12 can be prevented from unnecessarily bending and can be easily placed, allowing yield and reliability to improve.

Further, in the first embodiment, because the wave absorption sheet 84 is inserted into a space between the lower surface of the FPC 12 and the lower inner case 82, an effect of electromagnetic interference (EMI) can be suppressed.

Further, in the first embodiment, the recess 52b is formed on the lower surface of the upper cover 52 such that a part of the upper inner case 81 is fitted in the recess 52b during assembly. Thus, the upper inner case 81 can be easily attached to the upper cover 52.

The heat dissipation sheet 83 is not required to have a sheet shape as long as heat generated by the FPC 12 can be conducted to the upper cover 52. Similarly, the wave absorption sheet 84 is not required to have a sheet shape as long as a wave absorption member of the other shape can suppress EMI.

### Second Embodiment

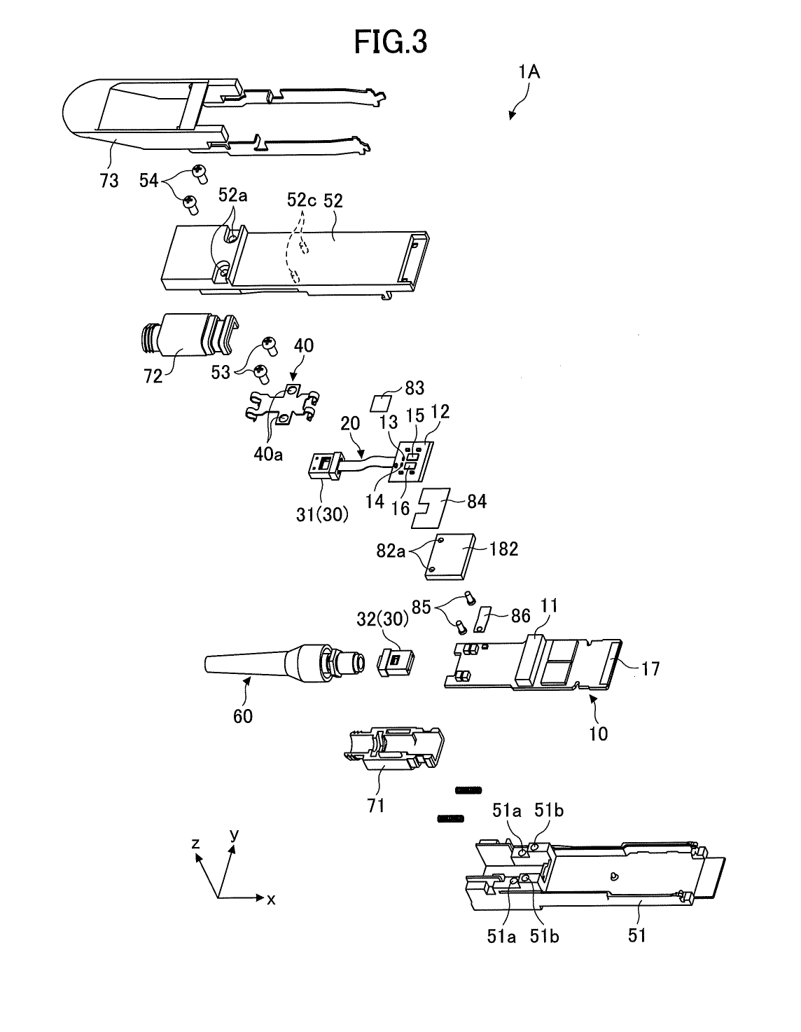

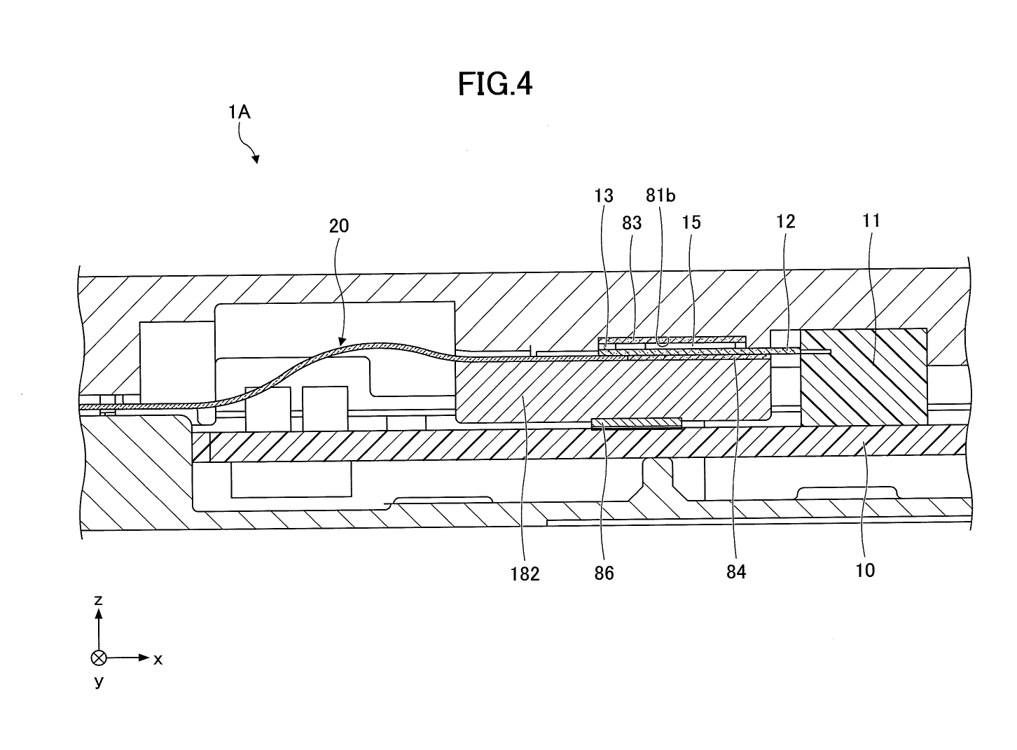

Referring to FIG. 3 and FIG. 4, a second embodiment will be described. FIG. 3 is an exploded perspective view illustrating an optical module 1A according to the second embodiment. FIG. 4 is a cross-sectional view of the optical module 1A.

As illustrated in FIG. 3 and FIG. 4, the optical module 1A differs from the optical module 1 in that the optical module 1A does not include a part corresponding to the upper inner case 81. The optical module 1A includes an inner case 182 corresponding to the lower inner case 82 according to the first embodiment. The inner case 182 is disposed on the lower surface of the FPC 12. The inner case 182 is placed so as to press the FPC 12 from the lower surface to the upper cover 52.

The heat dissipation sheet 83, the FPC 12, the wave absorption sheet 84, and the inner case 182 are stacked in this order, and are fixed to the upper cover 52 by inserting screws 85 into two through-holes 82a, 82a of the inner case 182 and fastening the screws to the upper cover 52. Further, the leaf spring 86 is placed between the inner case 182 and the printed circuit board 10.

The optical module 1A has a configuration in which the upper cover 52, the heat dissipation sheet 83, the electronic component such as the drive IC 15, the FPC 12, the wave absorption sheet 84, and the inner case 182 are stacked and assembled. The heat dissipation sheet 83 is held by five parts, the upper cover 52, the electronic component, the FPC 12, the wave absorption sheet 84, and the inner case 182. Namely, the optical module 1A can further reduce the number of parts involved in applying a pressing force to the heat dissipation sheet 83. Accordingly, assembly dimensional tolerance can be further reduced and efficiency of heat dissipation from the circuit devices device mounted on the FPC can be further improved.

### Third Embodiment

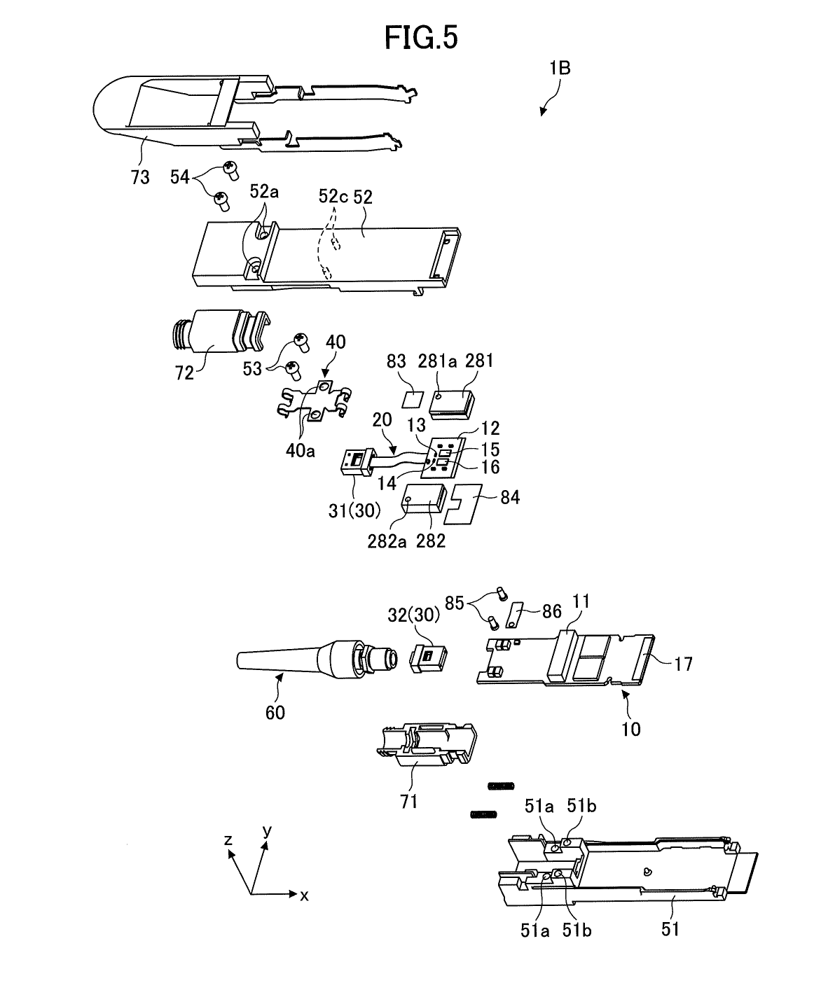

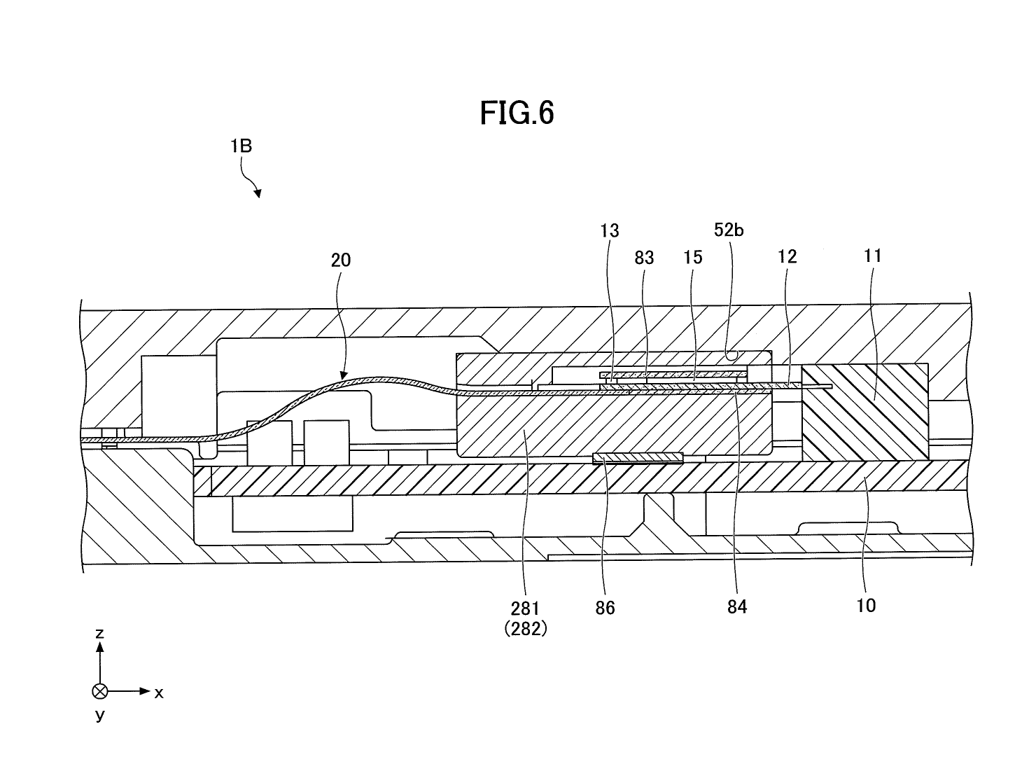

Referring to FIG. 5 and FIG. 6, a third embodiment will be described. FIG. 5 is an exploded perspective view illustrating an optical module 1B according to the third embodiment. FIG. 6 is a cross-sectional view of the optical module 1B.

As illustrated in FIG. 5 and FIG. 6, the optical module 1B differs from the optical module 1 in that the optical module 1B includes a pair of inner cases 281 and 282 covering the surfaces of the FPC 12 from both sides in the width direction.

The heat dissipation sheet 83, the FPC 12, and the wave absorption sheet 84 are stacked in this order, and held by the inner cases 281 and 282 while being accommodated inside the inner cases 281 and 282. The inner cases 281 and 282 are coupled to each other at an approximately center position in the width direction of the FPC 12. The screws 85 are inserted into through-holes 281a, 282a of the inner cases 281 and 282, and are fastened to the upper cover 52. Accordingly, the inner cases 281 and 282, the heat dissipation sheet 83, the FPC 12, and the wave absorption sheet 84 are integrally fixed to the upper cover 52. Further, the leaf spring 86 is placed between the inner cases 281 and 282 and the printed circuit board 10 located below the inner cases.

Similarly to the first embodiment, the optical module 1B can also reduce the number of parts involved in applying a pressing force to the heat dissipation sheet 83. Thus, assembly dimensional tolerance can be reduced, and also efficiency of heat dissipation from the circuit device mounted on the FPC 12 can be improved.

The inner cases 281 and 282 are not limited to a configuration in which an inner case is divided into two in y-direction. Any inner case may be adopted as long as the heat dissipation sheet 83, the FPC 12, and the wave absorption sheet 84 are accommodated inside the inner case and the upper surface and the lower surface of the FPC 12 are covered by the inner case. For example, a box-shaped inner case having an inner space and also having a lid on −x side can be used. In this configuration, after the lid is opened, the heat dissipation sheet 83, the FPC 12, and the wave absorption sheet 84 are inserted into the inner space from the opening. Then, by closing the lid, the heat dissipation sheet 83, the FPC 12, and the wave absorption sheet 84 can be accommodated in the inner case.

### Fourth Embodiment

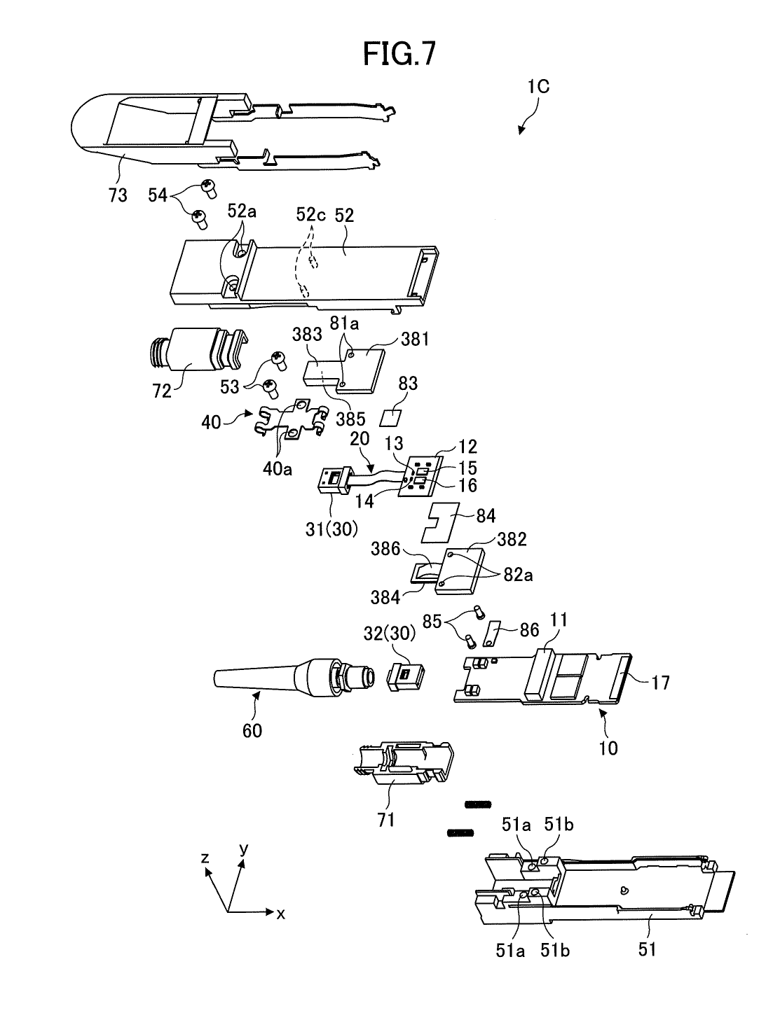

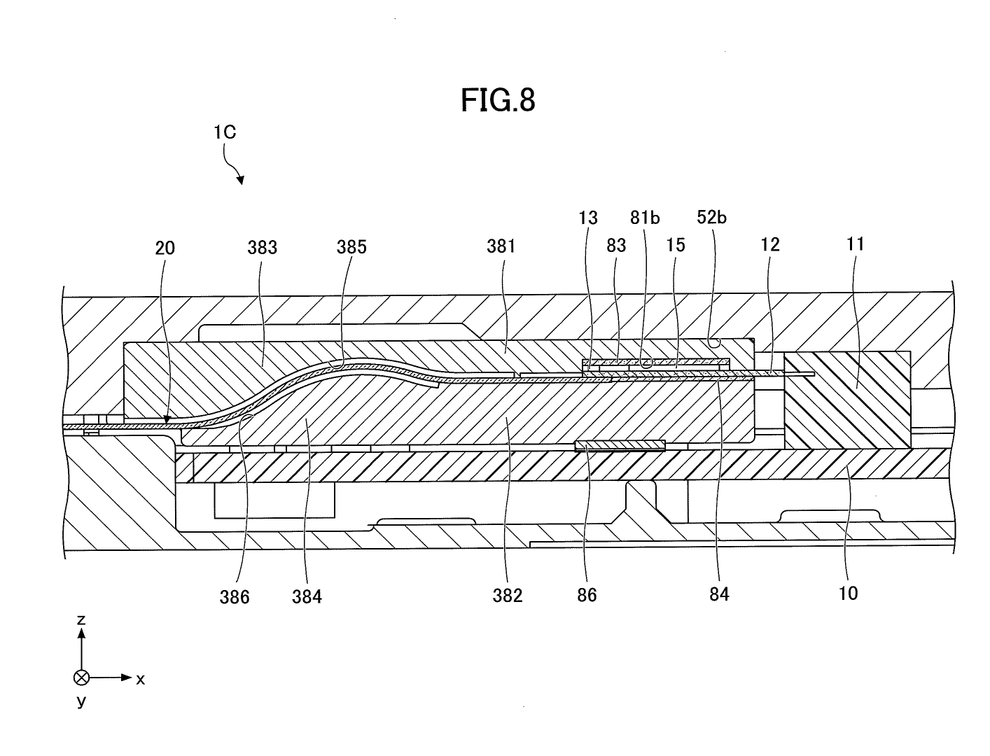

Referring to FIG. 7 and FIG. 8, a fourth embodiment will be described. FIG. 7 is an exploded perspective view illustrating an optical module 10 according to the fourth embodiment. FIG. 8 is a cross-sectional view of the optical module 10.

As illustrated in FIG. 7 and FIG. 8, the optical module 10 differs from the optical module 1 in that an upper inner case 381 and a lower inner case 382 have an upper guide 385 and a lower guide 386, respectively. The upper guide 385 and the lower guide 386 are used to position the optical waveguide 20 to be connected to the FPC 12.

As illustrated in FIG. 7, the upper inner case 381 has a holding portion 383 extending to the optical waveguide 20 (to −x side). As illustrated in FIG. 8, the lower surface of the holding portion 383 is provided with the upper guide 385 configured to hold the optical waveguide 20 from the upper side. Similarly, the lower inner case 382 has a holding portion 384 extending to the optical waveguide 20. The upper surface of the holding portion 384 is provided with the lower guide 386 configured to hold the optical waveguide 20 from the lower side. The upper guide 385 and the lower guide 386 are formed such that a space is created between the upper guide 385 and the lower guide 386 when the heat dissipation sheet 83, the FPC 12, and the wave absorption sheet 84 are held by the upper inner case 381 and the lower inner case 382.

As illustrated in FIG. 8, the upper inner case 381, the heat dissipation sheet 83, the FPC 12, the wave absorption sheet 84, and the lower inner case 382 are stacked and are fixed to the upper cover 52. In this state, the optical waveguide 20 is disposed along the space between the upper guide 385 and the lower guide 386, and thus, the shape of the optical waveguide 20 is fixed. Accordingly, it is possible to prevent the optical waveguide 20 from being deformed and to reduce loss and scattering of light traveling along the optical waveguide 20.

FIG. 7 and FIG. 8 illustrate the configuration in which the guides configured to position the optical waveguide 20 are provided on the upper inner Case 81 and the lower inner case 82 according to the first embodiment. However, the guides can also be applied to the second and third embodiments. When the guides are applied to the second embodiment, an element corresponding to the lower guide 386 is provided on the inner case 182 that is disposed on the lower surface of the FPC 12. Also, an element corresponding to the upper guide 385 is provided on the lower surface of the upper cover 52 at a position facing the inner case 182.

Although the embodiments have been specifically described above, the present disclosure is not limited to the above-described embodiments. These specific embodiments may be modified by a person skilled in the art as long as the features of the present disclosure are included. Elements and their arrangement, conditions, and shapes are not limited to the above-described embodiments and may be modified as necessary. It should be noted that combination of the elements of the above-described embodiments may be changed as long as no technical contradiction occurs.

In the above-described embodiments, the FPC 12 has been described as an example of a substrate on which the circuit devices are mounted. However, instead of the FPC 12, a rigid substrate may be used.

What is claimed is

1. An optical module comprising:
a housing having an upper cover and a lower cover;
a substrate having a circuit device mounted on its first surface;
a heat dissipation member configured to be in contact with the circuit device mounted on the substrate; and
at least one inner case having stiffness,
wherein the upper cover is disposed facing the first surface of the substrate, and the lower cover is disposed facing a second surface of the substrate, and
the inner case is disposed so as to press the substrate from the second surface of the substrate toward the upper cover.

2. The optical module according to claim 1, wherein the inner case is configured to cover both surfaces of the substrate.

3. The optical module according to claim 1, wherein a wave absorber is inserted into a space between said another surface of the substrate and the inner case.

4. The optical module according to claim 1, wherein the upper cover is formed such that a part of the inner case is fitted on the upper cover.

5. The optical module according to claim 1, wherein the inner case has a guide configured to position an optical waveguide to be connected to the substrate.
